(19) United States
(12) Patent Application Publication
(10) Pub. No.: US 2026/0096057 A1
(43) Pub. Date: Apr. 2, 2026

(54) Conformable Cold Plates

(71) Applicant: Microsoft Technology Licensing, LLC, Redmond, WA (US)

(72) Inventors: Oscar Farias MOGUEL, Seattle, WA (US); Dennis TRIEU, Redmond, WA (US)

(73) Assignee: Microsoft Technology Licensing, LLC, Redmond, WA (US)

(21) Appl. No.: 18/905,082

(22) Filed: Oct. 2, 2024

(51) Int. Cl. H05K 7/20; G06F 1/20

(52) U.S. Cl. CPC H05K 7/20254; G06F 1/20; H05K 7/20272

(57) ABSTRACT

The description relates to cold plate assemblies configured to cool computer chips. One example includes a manifold and a conformable cold plate positioned against the manifold to form a fluid passageway. The conformable cold plate is configured to conform to a shape of a computer chip positioned against the conformable cold plate when exposed to fluid pressure from the fluid passageway.

### BACKGROUND

Computing components, such as central processing units (CPUs), graphics processing units (GPUs), and memory, among others, allow an amazing number of operations to be performed per second. However, all of this capability undesirably produces large amounts of heat that must be removed from the computer components or damage will occur. Traditionally, air cooling was sufficient to remove this excess heat. However, as computing performance has increased air cooling has been replaced with liquid cooling.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the FIG. and associated discussion where the reference number is first introduced.

FIG. 1A is an exploded perspective view of an example system implementation in accordance with the present concepts.

FIG. 1B is an assembled perspective view of the example system implementation of FIG. 1A.

FIG. 1C is a side view of the example system implementation of FIG. 1B.

FIG. 2 is a side view of an example conformable base plate implementation in accordance with the present concepts.

FIG. 3 is a side view of a rigid base plate.

FIG. 4 is a side view of another example conformable base plate implementation in accordance with the present concepts.

FIG. 5 is a side view of another example conformable base plate implementation in accordance with the present concepts.

FIG. 6 is a side view of another example conformable base plate implementation in accordance with the present concepts.

FIG. 7 shows a flowchart of an example conformable base plate method in accordance with the present concepts.

### DESCRIPTION

The present concepts relate to cooling computing components, such as those on computer chips (e.g., integrated circuits). Computing components, such as central processing units (CPUs), graphics processing units (GPUs), and memory, among others, allow an amazing number of operations to be performed per second. However, all of this capability undesirably produces large amounts of heat that must be removed from the computing components or damage will occur. Traditionally, air cooling was sufficient to remove this excess heat. However, as computing performance has increased air cooling has been replaced with liquid cooling.

Liquid cooling can be accomplished with a cold plate assembly. The cold plate assembly positions a base plate proximate to the computer chip. Traditionally, the base plate has been very rigid. In contrast, the computer chip tends to change shape from ambient temperatures to operational temperatures (e.g., thermal cycling). The shape changes tend to be more pronounced on larger computer chips. These shape changes create a technical problem involving inefficiencies in thermal transfer between the computer chip and the base plate. These inefficiencies can damage the computer chip and/or cause the computer chip to be operated below its design parameters (e.g., throttling) to reduce overheating. The present concepts provide a technical solution involving a conformable base plate that follows the shape of the computer chip during the shape changes associated with thermal cycling. The conformable base plate maintains thermal transfer rates at designed levels for the life of the computer chip. This increases the performance of the computer chip and decreases resource usage associated with functioning of the computer chip and the liquid cooling system. These and other aspects are described below.

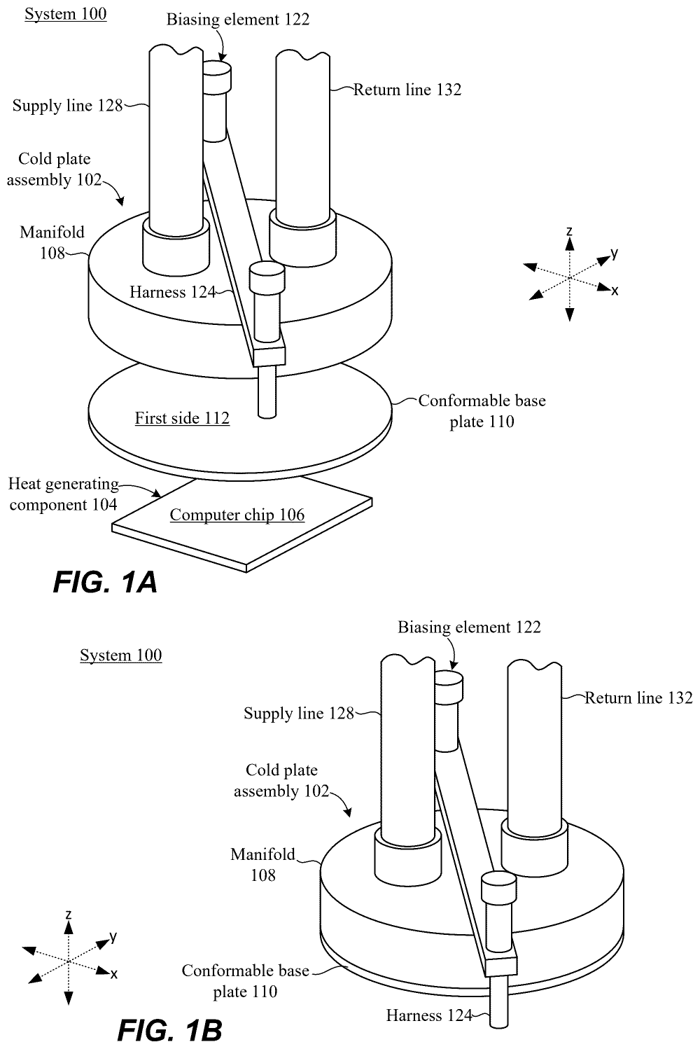

FIGS. 1A-1C collectively show an example system 100 that can employ the present concepts. In this case, the system 100 includes a cold plate assembly 102 that is configured to cool (e.g., remove heat from) a heat generating component 104, such as computer chip 106.

In this implementation, the cold plate assembly 102 includes a manifold 108 and a conformable base plate 110. The manifold 108 has a perimeter extending around a center. Similarly, the conformable base plate 110 has a perimeter and a center. A first side 112 of the conformable base plate 110 faces the manifold and can be secured to the manifold 108 around the perimeters to collectively define a fluid passageway 114 (FIG. 1C). The first side 112 of the conformable base plate 110 can include heat transfer structures 116 that extend into the fluid passageway 114.

A thermal interface material (TIM) 118, such as a thermal paste can be positioned between a second side 120 of the conformable base plate 110 and the computer chip 106. The TIM 118 is configured to contact the computer chip 106 and the conformable base plate 110 and to efficiently move heat from the computer chip to the conformable base plate. The TIM moves heat much more efficiently than air. A biasing element 122, such as a harness 124 is configured to bias the computer chip 106 and the conformable base plate 110 towards one another and against the TIM. In this case, the computer chip 106 is positioned on a substrate 126, such as a printed circuit board. The harness 124 biases the substrate 126 toward the cold plate assembly 102 and thus, the computer chip 106 toward the conformable base plate 110. Thus, the system 100 is designed for heat to flow from the computer chip 106 through the TIM 118 to the conformable base plate 110. Any spaces in the TIM (e.g., areas lacking TIM) between the computer chip 106 and the conformable base plate 110 will decrease the heat transfer rate.

A supply line 128 supplies coolant fluid 130 to the fluid passageway 114. Coolant fluid 130 flows through the fluid passageway 114. Heat transfer structures 116 extend upwardly from the conformable base plate 110 into the fluid passageway 114. The heat transfer structures 116 are configured to increase contact area between the conformable base plate 110 and the coolant fluid 130 and thus increase the rate of heat transfer from the conformable base plate to the coolant fluid. The now heated coolant fluid leaves the fluid passageway 114 via return line 132.

As mentioned above, efficient heat removal (e.g., thermal transfer) from the computer chip 106 to the coolant fluid 130 depends upon the presence of TIM 118 between the computer chip 106 and the conformable base plate 110. The conformable base plate 110 includes features that allow the conformable base plate to follow shape changes (e.g., deformation or warpage) of the computer chip 106 in the z reference direction. This deformation tends to increase with increasing dimensions of the computer chip in the x and/or y reference directions). The propensity of the conformable base plate 110 to follow shape changes of the computer chip 106 tends to retain the TIM 118 between the computer chip 106 and the conformable base plate 110. Retaining the TIM 118 allows efficient heat transfer from the computer chip 106 to the conformable base plate 110. The conformable nature of the conformable base plate 110 can be facilitated by several parameters including thickness in the z reference direction, composition, the presence of heat transfer structures on a given region of the conformable base plate, and/or a configuration of the heat transfer structures 116 on individual regions of the conformable base plate. For instance, in the implementation shown in FIG. 1C, the peripheral region 134 of the conformable base plate that does not contact (e.g., overly) the computer chip does not have heat transfer structures. An intermediate region 136 has a first type of heat transfer structures 116 and an inner or central region 138 has a second type of heat transfer structures 116.

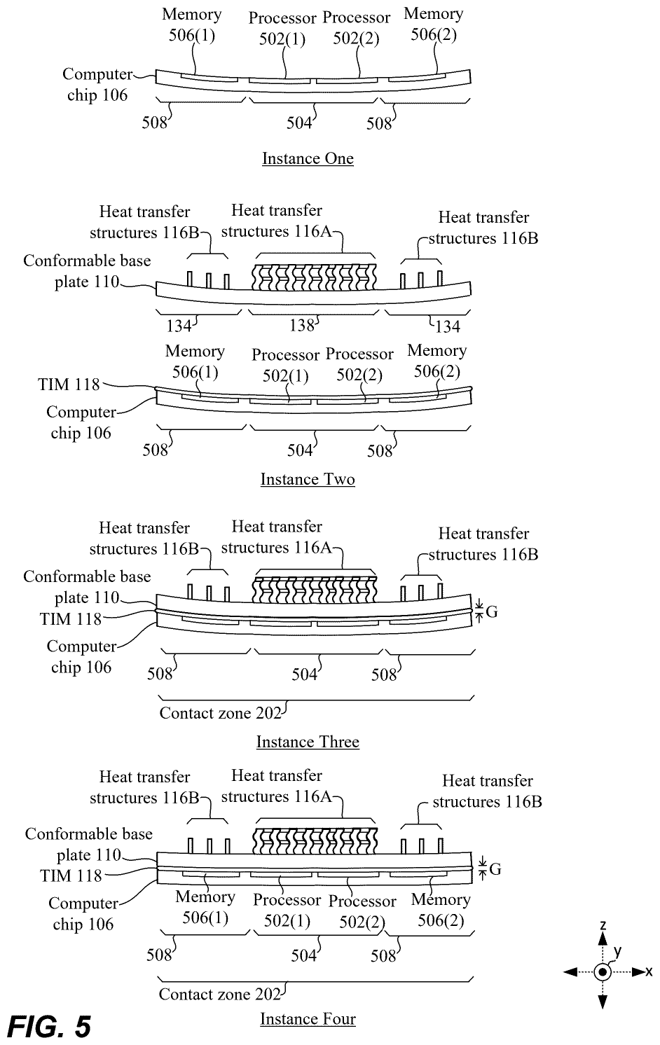

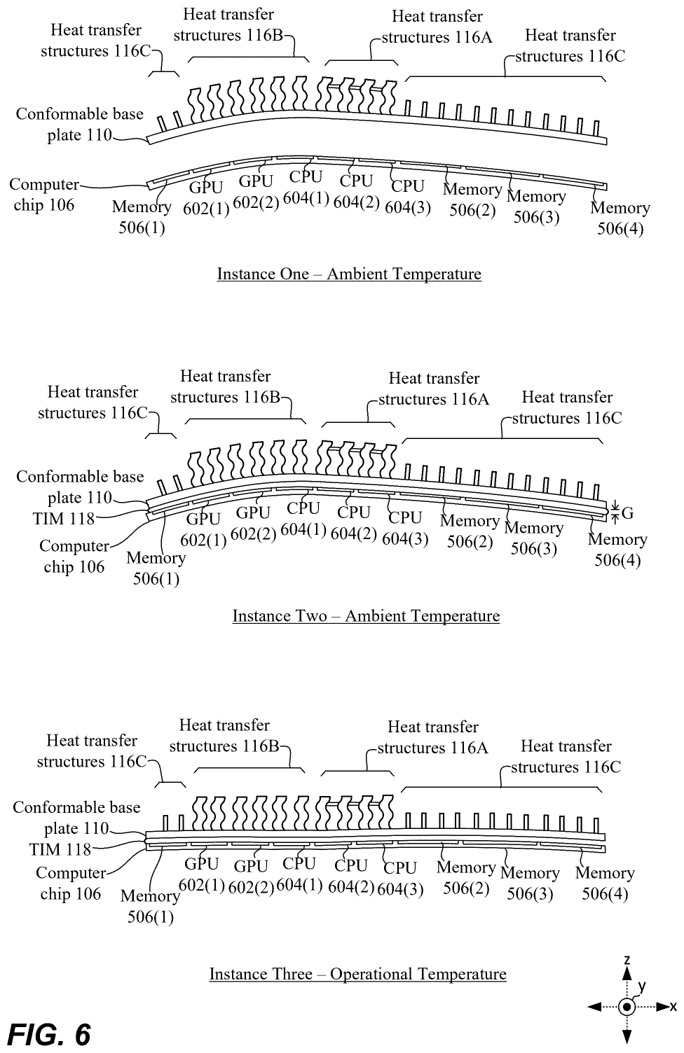

Varying the types of heat transfer structures 116 is described in more detail below relative to FIGS. 5 and 6. Briefly, heat transfer structures 116 can be selected based upon the type of underlying computer components on the computer chip 106 (e.g., how much heat is produced under a region of the conformable base plate). The heat transfer structures 116 for an individual region of the conformable base plate 110 can alternatively be selected based upon the tendency of the underlying region of the computer chip 106 to deform (e.g., bend or be displaced) in the z reference direction.

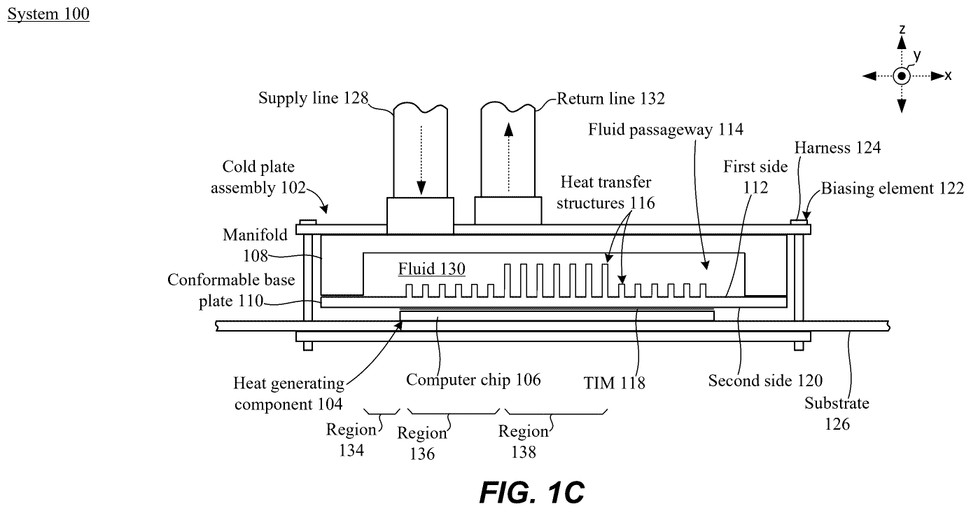

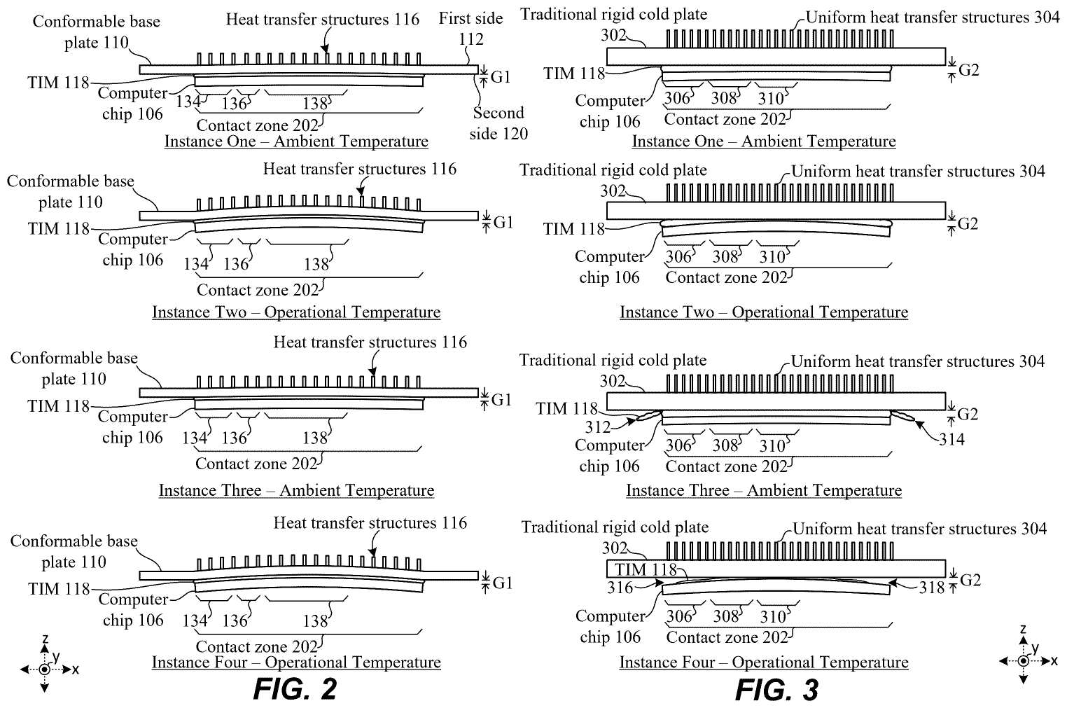

FIGS. 2 and 3 show a series of comparisons that illustrate some of the present thermal transfer efficiency concepts. FIG. 2 shows an example conformable base plate 110 with associated computer chip 106. TIM 118 is positioned along a contact zone 202 between the computer chip 106 and the conformable base plate 110. FIG. 3 shows a traditional rigid cold plate 302. TIM 118 is positioned along contact zone 202 between the computer chip 106 and the traditional rigid cold plate 302. Note that to avoid clutter on the drawing page other components of the cold plate assembly, such as the manifold are omitted in FIGS. 2 and 3.

The traditional rigid cold plate 302 is relatively inflexible (e.g., rigid) in the z reference direction. This rigidity is due in part to the thickness of the rigid cold plate in the z reference direction. Also, a set of uniform heat transfer structures 304 can contribute to the rigidity by imparting additional resistance to bending in the z reference direction on the traditional rigid cold plate 302.

For purposes of explanation, FIGS. 2 and 3 show identical computer chips 106 experiencing thermal cycling. Instance One shows the computer chips at an initial ambient temperature (e.g., approximately 25 degrees Celsius) prior to operation. Instance Two shows the computer chips at operating temperatures (e.g., approximately 100 degrees Celsius). Instance Three shows the computer chips back at ambient temperature and Instance Four once again shows the computer chips up at operating temperatures. In this illustrated configuration, the computer chips 106 start out relatively planar at ambient temperatures and deviate away from the planar configuration (e.g., warp in a convex manner) at operating temperatures. In other implementations, the computer chip may start bent or cupped in either a convex or concave shape and warp towards a planar configuration (e.g., become less bent or cupped) as it heats up. Such configurations are described below relative to FIGS. 5 and 6.

At Instance One, FIG. 2 shows TIM 118 filing a gap (G1) along the contact zone 202 between the computer chip 106 and conformable base plate 110. The gap G1 is generally uniform along the contact zone in the illustrated x reference direction (and also in the y reference direction). For example, the gap G1 can be considered to be generally uniform when the gaps at all locations along the contact zone are within +/−20% of one another. In other examples, the gaps along the locations are generally uniform to within +/−10% of one another.

Similarly, at Instance One, FIG. 3 shows TIM 118 filing a gap (G2) along the contact zone 202 between computer chip 106 and the traditional rigid cold plate 302. At this point, the gap G2 is generally uniform as illustrated along the x reference axis. Note that to accommodate relative movement (e.g., bending of the computer chip relative to traditional rigid cold plate 302), gap G2 is greater in the z reference direction than gap G1 between the conformable base plate 110 and the computer chip 106 of FIG. 2. The wider gap G2 can decrease the thermal transfer rate because while TIM has a higher thermal transfer rate than air, it tends to have a lower thermal transfer rate than the cold plate material.

Instance Two in both FIGS. 2 and 3 shows the computer chips 106 have heated up to operational temperatures. This occurs when electrical energy is used to perform computer operations on the computer chip and some of the electrical energy is converted to heat energy. This heating physically changes the shape of the computer chip. Briefly, the shape changes may be caused by different material properties, such as coefficient for thermal expansion (CTE) of different regions of the computer chip. These different material properties create forces on the computer chip that can cause warpage of the computer chip in the z reference direction.

Instance Two of FIG. 2 shows the shape of the conformable base plate 110 following (e.g., conforming to) the shape changes of the computer chip 106. The conformable base plate 110 can be designed to readily change shape when exposed to relatively small physical forces (e.g., forces at the level produced by the deforming computer chip and/or fluid pressure from coolant fluid in the fluid passageway). This propensity to readily change shape can be achieved via one or more design parameters. These parameters can include thickness of the conformable base plate 110 in the z reference direction, composition of the conformable base plate 110, type and location of heat transfer structures 116, and/or prestressing of regions of the conformable base plate 110, among others.

The tendency of the conformable base plate 110 to follow shape changes in the computer chip 106 maintains the gap G1 between the conformable base plate 110 and the computer chip 106. That is, the gap G1 shown in Instance Two is overall equivalent to the gap G1 of Instance One. Further, as viewed along the profile in the x and y reference directions, the gap G1 is relatively uniform at individual locations along the contact zone 202, such as within +/−20% and in some cases within +/−10%, when compared to one another in Instance One and Instance Two. Stated another way, the gap G1 of peripheral region 134, intermediate region 136, and inner or central region 138 are approximately equal when comparing Instance One and Instance Two. Further, individual regions generally maintain the same gap even when the shape of the computer chip changes (e.g., the gap G1 of peripheral region 134 is approximately equal in Instance One and Instance two, the gap G1 of intermediate region 136 is approximately equal in Instance One and Instance two, and the gap G1 of central region 138 is approximately equal in Instance One and Instance two). Stated another way, an individual location along the contact zone 202 will have a gap G1 that varies by less than 20% from ambient temperature to operating temperature, and in some cases the gap of the individual location will vary less than 10% from ambient temperature to operating temperature. This gap uniformity can be obtained at least in part by the compliant nature of the conformable base plate 110 to follow changes to the shape of the computer chip 106. Thus, in relation to the gap G1, the terms “approximately equal“ and/or ”generally uniform” mean within 20% or less and in some implementations within 10% or less.

In contrast, as shown at Instance Two of FIG. 3, traditional rigid cold plate 302 is rigid or inflexible (e.g., non-conformable) when exposed to forces at the level imparted by the computer chip 106 and/or coolant fluid. This results in the computer chip 106 changing shape relative to the traditional rigid cold plate 302. This relative shape change causes the gap G2 to change along and/or within the contact zone 202. For instance, when comparing peripheral region 306, the gap G2 is wider in Instance Two than Instance One. Conversely, when comparing central region 310 the gap G2 is smaller in Instance Two than Instance One. Further, along its length, the gap varies significantly. For purposes of explanation, the gap is described relative to peripheral region 306, intermediate region 308, and central region 310. Gap variation is evidenced in Instance Two at the peripheral region 306 where gap G2 is approximately twice as wide as the gap G2 of the central region 310. Narrowing of the gap G2 in the central region 310 forces (e.g., squeezes) TIM material out toward the peripheral region 306.

FIGS. 2 and 3 show additional shape changes to the computer chips 106 at Instance Three. The shape changes could be associated with cooling of the computer chips to ambient temperature, such as when the computer chips are performing less or no computer operations compared to Instance Two. In this example, the computer chips have returned to the generally planar or more planar shape of Instance One compared to the more convex shape of Instance Two.

In FIG. 2, at Instance Three, the shape of the conformable base plate 110 has followed the shape of the computer chip 106 and as a result is also more planar than Instance Two. The tendency of the conformable base plate 110 to bend when exposed to forces of the computer chip 106 has kept the gap G1 relatively uniform across the contact zone 202 (e.g., at the peripheral region 134, intermediate region 136, and central region 138) at Instance One, Instance Two, and Instance Three. Maintaining a relatively uniform gap G1 (both overall and at individual locations) ensures that the TIM 118 continues to extend between (e.g., thermally connect) the computer chip 106 and the conformable base plate 110 along the entire contact zone 202. Further, by not having to accommodate shape changing of the computer chip 106 against (e.g., relative to) a rigid base plate, the gap G1 can be narrower in the z reference direction than the gap G2 of the traditional design shown in FIG. 3.

In FIG. 3, as shown at Instance Three, the computer chip 106 has also returned to a shape similar to Instance One. Recall that at Instance Two, some of the TIM material had been forced from the central region 310 towards the peripheral region 306. When the computer chip flattens from the warped shape of Instance Two to the relatively more planar shape of Instance Three, the TIM material in the peripheral region 306 will be squeezed between the computer chip and the traditional rigid cold plate 302. This squeezing will eject some of the TIM 118 from the contact zone 202 as indicated at 312 and 314 and may be referred to as ‘TIM pump out.’ This ejection of TIM means that the volume of TIM in the contact zone 202 between the computer chip 106 and the traditional rigid cold plate 302 is less than in Instance One.

Instance Four of FIGS. 2 and 3, show the computer chip once again deformed similar to the shape shown in Instance Two. This deformation can be due to thermal expansion as the computer chip heats while performing computing operations (e.g., is at operational temperature). FIG. 2 shows the conformable base plate 110 once again following the shape change of the computer chip 106 similar to Instance Two. Looking at Instance Four, the gap G1 remains consistent across the contact zone (e.g., less than 20% variation in gap along the contact zone, for example). The gap G1 is also similar to the gap G1 in Instances One through Three (e.g., the gap at an individual location along the contact zone remains relatively constant in Instances One through Four despite the changing shape of the computer chip 106). This gap continuity provides a technical solution in that the TIM 118 continues to span the gap G1 along the entire contact zone 202 as the shape of the computer chip 106 changes; even when the shape changes multiple times. This technical solution maintains the thermal transfer rate from the computer chip 106 to the conformable base plate 110 through multiple computer chip shape changes because the conformable nature of the conformable base plate maintains the gap distance and thus the TIM 118 stays in place and extends between the computer chip 106 and the conformable base plate 110 along the entire contact zone 202. This is in stark contrast to the situation with the traditional rigid cold plate 302.

Instance Four of FIG. 3 shows computer chip 106 once again deformed similar to Instance Two. However, recall that some of the TIM 118 was squeezed out of the contact zone 202 at Instance Three. Now the Gap G2 has expanded at the peripheral region 306 and the reduced amount of TIM does not span across the gap G2 at this portion of the contact zone 202 as indicated at 316 and 318. Lacking TIM 118 to thermally couple the computer chip 106 to the traditional rigid cold plate 302 greatly reduces thermal transfer across the contact zone 202. Accordingly, the computer chip 106 temperature will rise if computer operations are maintained at the levels that were sustainable at Instance Two. The rising temperature can degrade the computer chip and decrease its functional lifespan. Accordingly, the computer chip 106 would have to be operated at a reduced level to maintain the same operating temperatures as could be maintained at Instance Two when TIM 118 spanned the entire contact zone 202.

Thus, the traditional rigid cold plate induces failure modes such as TIM pump out. The presence of TIM pump out in the traditional computer chip/cold plate assembly will eventually lead to a significant degradation in heat transfer and constant thermal events that will not only decrease the performance of the computer chip but it will also hinder its reliability.

In contrast, the present concepts provide conformable base plates 110 that provide technical solutions to eliminate the above-mentioned thermal problems. Moreover, the allowed deformation of the conformable base plate 110 will increase the rate of heat exchange at the conformable base plate as this smaller gap G1 between surfaces will allow for a lower thermal resistance in the stack (e.g., the computer chip 106 and the conformable base plate 110).

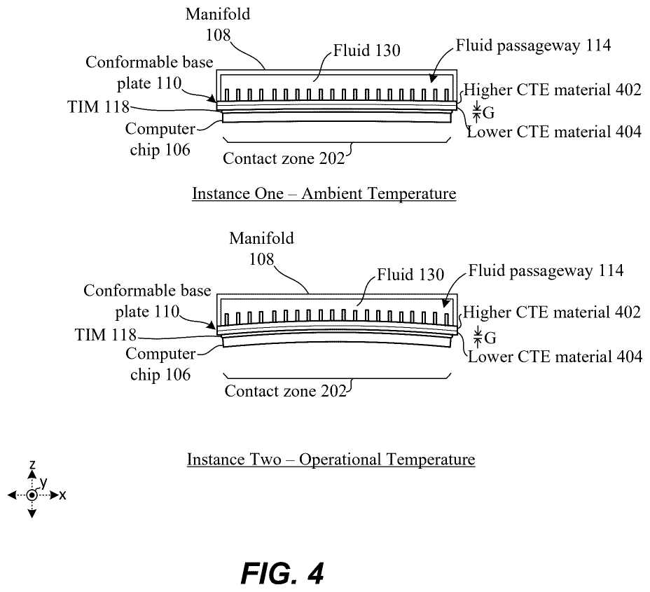

In the implementation described above relative to FIG. 2, the conformable base plate 110 is configured to passively bend when experiencing forces imparted by the computer chip 106 and/or by the coolant fluid (130, FIG. 1C). Some implementations may include a conformable base plate configuration that actively bends or deforms in concert with the computer chip 106. This active bending can reduce or eliminate the force from the computer chip 106 and/or coolant fluid that bends the conformable base plate 110. Once such example implementation is described below relative to FIG. 4.

FIG. 4 shows another example conformable base plate 110 positioned in manifold 108 with coolant fluid 130 flowing in the fluid passageway 114 (e.g., volume) defined between the conformable base plate and the manifold. In this implementation, the conformable base plate 110 includes a first layer of higher CTE material 402 and a second layer of relatively lower CTE material 404 (e.g., a bi-metallic configuration). At Instance One at ambient temperatures, the computer chip 106 and the conformable base plate 110 are relatively planar and maintain a relatively uniform and narrow gap G along the entire contact zone 202. At Instance Two at operating temperatures, both the computer chip 106 and the conformable base plate 110 deform to approximately equal extents. In this case, the bi-metallic configuration causes the conformable base plate 110 to undergo shape changes due to CTE that are very similar to those of the computer chip. Thus, the conformable base plate 110 actively approximates shape changes of the computer chip rather than relying solely on external forces to change the shape of the conformable base plate 110. The conformable base plate 110 can also be conformable to forces from the computer chip 106 and/or imparted by the coolant fluid 130 and will follow shape changes of the computer chip 106 with reduced or no forces from the computer chip. Other structural configurations of the conformable base plate 110 are contemplated to reduce force levels from the computer chip 106 and/or coolant fluid 130 that will deform the conformable base plate 110.

Viewed from one perspective the present concepts include conformable base plates 110 that are configured to deform when exposed to forces from the computer chip 106 and/or the coolant fluid 130. Some implementations of these conformable base plates 110, such as the one illustrated in FIG. 4, can include a construction that causes the conformable cold plate to actively approximate the various shapes of the computer chip. These shape approximations can reduce the forces imparted on the conformable cold plate by the computer chip and/or the coolant fluid while still achieving shape change and maintaining a uniform gap G along the contact zone 202, such as the shape transition from Instance One to Instance Two and back to Instance One.

FIG. 5 shows another example conformable base plate 110 illustrated relative to computer chip 106. In this view the computer chip 106 includes two processors 502 in a central region 504 and two memory components 506 in a peripheral region 508.

Instance One shows the computer chip 106 at ambient temperature. At this temperature, the computer chip has a concave shape opening upward (e.g., in the positive z direction). In this case, the central region 504 is somewhat flatter (e.g., closer to planar) and the peripheral region 508 is more cupped or curved upward. This computer chip 106 is configured to deform or flex towards a relatively more planar configuration at operating temperatures. Further, more of the shape changes occur in the peripheral region 508 than in the central region 504.

Instance Two shows conformable base plate 110 configured to operate cooperatively with the computer chip 106. At this point, TIM 118 is positioned on the computer chip 106, but the conformable base plate 110 is not assembled together with the computer chip. In this case, the conformable base plate 110 has a shape at ambient temperature that approximates the shape of the computer chip at ambient temperature. Further, the conformable base plate 110 is configured to bend more in regions where the computer chip 106 is configured to bend more and to bend less where the computer chip is configured to bend less. In this case, the tendency to bend or not bend is promoted by the types and/or locations of the heat transfer structures 116. For instance, the processors 502 of the central region 504 tend to generate relatively large amounts of heat during operation.

Thermal transfer above the processors 502 is enhanced by the presence of a subset of relatively large heat transfer structures 116A spaced at a relatively high density (e.g., close together) and overlying the processors 502. The heat transfer structures 116A can also be configured to reduce the tendency of the underlying central region of the conformable base plate 110 to flex compared to other regions of the conformable base plate 110. In this example the heat transfer structures 116A are interconnected with one another in the x and y reference directions to create a lattice configuration. The lattice configuration of the heat transfer structures 116A stiffens the underlying central region 504 of the conformable base plate 110 in relation to z direction shape change.

In contrast, the memory components 506 are positioned on the peripheral region 508 of the computer chip 106. The peripheral region 508 tends to change shape more than the central region 504 in this implementation. Further, the memory components 506 produce less heat during operation than the processors 502. Thus, the heat transfer rates above the memory components 506 do not have to be as high as above the processors 502 to provide sufficient heat dissipation. For both of these reasons, a subset of heat transfer structures 116B positioned above the memory components 506 can be selected based upon different criteria than those over the processors 502. In this example, the heat transfer structures 116B are sparser (e.g., fewer per unit area in the xy reference plane) than the heat transfer structures 116A.

Also, in this example the heat transfer structures 116B are pin type structures (e.g., similar to a stalagmite shape) that are not interconnected to one another (in either the x or y reference directions). This configuration allows adequate thermal transfer from the memory components 506 through the TIM 118, into the conformable base plate 110 and the heat transfer structures 116B to the coolant fluid, while promoting the conformable nature of the conformable base plate 110 to follow shape changes of the computer chip 106. Thus, when considered in cross-sectional views taken orthogonal to the first and second sides of the conformable cold plate (e.g., along the xz or yz reference planes) the heat transfer structures are not all uniform. In this example, the heat transfer structures 116A over the processors are not the same as the heat transfer structures 116B over the memory, for example. The non-uniformity can relate to height, spacing, and/or interconnectedness, among others. The non-uniformity provides a technical solution that allows sufficient cooling for specific underlying computing components and associated heat production while also promoting or limiting the tendency of regions of the conformable base plate 110 to bend.

Note that the computer chip 106 may include additional components that are not visible in these views. For instance, these views are taken along the xz reference plane, but other views along the yz reference plane and/or planes between the xz reference plane and the yz reference plane may include additional or alternate computer components. Thus, the conformable base plate concepts explained relative to the xz reference plane can be applied to the entire computer chip 106. For instance, 3D measurements may be taken of the computer chip in isolation similar to Instance One. The 3D shape of the conformable base plate 110 shown in Instance Two can be matched to the 3D shape of the computer chip as well as the type and location of the computing components on the computer chip.

Instance Three remains at ambient temperature and shows the conformable base plate 110 assembled with the computer chip 106 with the TIM 118 spanning between them along the contact zone 202. The conformable base plate 110 being pre-shaped to approximate the shape of the computer chip 106 promotes the gap G being uniform along the contact zone 202.

Instance Four shows the computer chip 106 warmed to operating temperatures. The computer chip 106 has warped or deformed toward the planar configuration with a majority of the deformation occurring on the peripheral region 508. The conformable base plate 110 has deformed with the computer chip 106. The relatively large and interconnected heat transfer structures 116A stiffen the conformable base plate 110 over the processors 502 while providing relatively high heat dissipation (e.g., thermal transfer). The relatively sparse and pin-shaped heat transfer structures 116B allow the periphery of the conformable base plate to readily deform with the computer chip 106. These configurations serve to maintain relatively uniform gap G along the contact zone 202 in Instance Four when compared to Instance Three. Further the relatively large and interconnected heat transfer structures 116A transfer relatively large amounts of heat to the coolant fluid to avoid overheating of the processors 502 during designed operational parameters.

FIG. 6 shows another example conformable base plate 110 illustrated relative to computer chip 106. Various dimensions of computer chips 106 can be employed. For instance, the computer chip 106 can have a thickness in the z reference direction in a range of 400 to 1,000 microns, in some implementations. The conformable base plate 110 can have a thickness in the z reference direction in a range of 100 to 500 microns, in some implementations. So, for instance, the thickness of the compliant base plate may be 25% to 100% of a thickness of the computer chip, in some examples. In relation to the xy dimensions, computer chips 106 can have outer dimensions (e.g., width, length, or diameter) from 20 millimeters to 500 millimeters, in some implementations. Stated in relation to total area, some of these example computer chips have areas from 650 square millimeters (mm²) to 40,000 mm² or more, in some implementations. The conformable cold plate 110 tends to be slightly larger to allow association with the cold plate manifold around the periphery. In this illustrated case, computer chip 106 is a relatively large computer chip with dimensions in the x and/or y directions in a range of about 200 millimeters to about 500 millimeters. The relatively large computer chips are prone to deviate from a planar configuration and because of their large size the deviation is more pronounced. For instance, the deviation can be more than 250 microns in some examples.

Instance One shows the computer chip 106 and the conformable base plate 110 in an unassembled state at ambient temperatures. Instance Two shows the computer chip 106 and the conformable base plate 110 in an assembled state at ambient temperatures. The shape of the conformable base plate creates a unform gap G between the computer chip 106 and the conformable base plate 110. The gap G is filled with TIM 118.

This implementation is similar to the implementation of FIG. 5 where the computer chip 106 is formed having a non-planar shape but gets closer to planar as it warms. This is evidenced by comparing Instance One and Instance Two with their ambient temperatures to Instance Three at higher operational temperatures. However, unlike the implementation of FIG. 5, when viewed along the xz plane as shown in FIG. 6, this implementation has an asymmetric configuration (e.g., the curve or profile of the left side does not match the curve or profile of the right side).

This implementation of computer chip 106 is also asymmetric in that the components on the left are not a mirror image of those on the right. In this case, as viewed along the xz plane, starting from the left side of the drawing page the computer chip includes memory 506(1), processors in the form of two graphics processing units (GPUs) 602, and three central processing units (CPUs) 604, as well as memory 506(2), 506(3), and 506(4). Note that computer chip 106 can include these components (e.g., CPUs 604, GPUs 602, and memory 506) on a single (silicon) substrate. Other implementations may assemble the components together as a multi-die chipset (e.g., multiple chiplets integrated in a single package) to form computer chip 106.

In this case, relatively large amounts of heat are generated by the GPUs 602 and the CPUs 604 during operation compared to the memory 506(1)-506(4). Thus, more extensive heat transfer structures 116A and 116B can be positioned over the processors than the heat transfer structures 116C over the memory 506. However, the computer chip 106 changes shape asymmetrically proximate to the GPUs 602 and CPUs 604. Thus, in this implementation heat transfer structures 116A are configured to provide both relatively high heat transfer rates as well as structural integrity to limit bending of the conformable base plate 110. Similar to FIG. 5, these heat transfer structures 116A are interlaced or cross-braced with one another in the x and/or y reference directions to provide structural stiffness to the underlying region of the conformable base plate. Heat transfer structures 116B are configured to provide more contact with the coolant fluid per unit volume than the heat transfer structures 116C associated with the memory 506. However, the heat transfer structures 116B are configured to provide less structural stiffness to the underlying region of the conformable base plate 110 to resist localized bending forces when compared to heat transfer structures 116A. For instance, in this case the heat transfer structures 116B are freestanding rather than being interconnected with one another. The freestanding heat transfer structures 116B can provide some localized stiffness by employing various structural configurations. In this example freestanding heat transfer structures 116A and 116B employ triply periodic minimal surfaces (TPMS) that both enhance their rigidity and promote efficient heat exchange. Further, heat transfer structures 116A employ a lattice configuration to further stiffen the underlying region of the conformable base plate 110. In comparison, heat transfer structures 116C over the memory 506 provide heat transfer and the lowest amount of structural stiffness. Thus, heat transfer structures 116B are configured to provide more local structural stiffness than heat transfer structures 116C and less local structural stiffness than heat transfer structures 116A. These multiple (e.g., three) heat transfer structure configurations can be selected to achieve the desired degree of flexibility and heat transfer rates over individual regions of the conformable base plate 110 to match localized bending of the computer chip 106.

Instance Three shows the computer chip 106 and the conformable base plate both deformed toward a planar configuration at operational temperatures (e.g., higher temperatures than Instance One and Instance Two).

This design provides a technical solution in that the shape of the conformable base plate 110 approximates the shape of the computer chip 106 at ambient temperature before assembly. This creates a uniform gap that is occupied by TIM 118 to increase the thermal transfer rate from the computer chip 106 to the conformable base plate 110. As the shape of the computer chip 106 changes due to heating of the computer chip, the conformable base plate readily follows the shape change and maintains the gap G. This can be seen by comparing the gap overall along the contact zone 202 and at individual locations along the contact zone at ambient and operational temperatures. This eliminates pumping out of TIM 118 from the gap as occurs with traditional designs and allows the present implementation to maintain the designed level of thermal transfer from the computer chip 106 to the conformable base plate 110 through the TIM 118 for the life of the computer chip (e.g. through many heating and cooling cycles).

Some of the present concepts introduced above relate to improved fluid cooling concepts including conformable base plates configured to cool computer chips 106. The fluid cooling concepts include the new conformable cold plate designs that incorporate a configuration that allows a certain, pre-defined, deformation to compensate for the large warpage of some computer chips, such as new large diameter computer chips that include GPUs and CPUs.

Upcoming generations of computer chips with their multiple CPUs and GPUs are growing both in size and power. In addition, some of the novel chip architectures include an embedded array of several chiplets, which have different material properties, such as the coefficient for thermal expansion (CTE). Moreover, the manufacturing of this new generation of chips requires a series of processes that sometimes require a high temperature thus also inducing displacements to the assembly. These characteristics produce rapid expansion and contraction that occurs at different rates on different regions of the computer chip (e.g., different computing components have different rates of expansion and contraction from other computer chip components). In order to alleviate this condition, as well as to reduce the strain of the components due to the CTE mismatch effect, the chip manufacturers may prescribe a deformation at ambient temperature (25 C) that eventually will flatten out its surface at operating temperature (above 100 C)—recall the examples described above relative to FIGS. 5 and 6. For example, computer chips can produce a surface displacement of up to 300 microns or even larger.

In contrast, the traditional cold plate comprises a rigid base plate from which the heat produced by the computer chip is rejected into the coolant fluid. The total warpage of the traditional rigid cold plate base is substantially lower than that of the computer chip due to its simpler manufacturing process. In addition, the surface of the traditional rigid cold plate base does not dynamically warp due to changes in temperature, thus producing misalignments in the overall gap between these surfaces and pushing out the TIM that lies in between.

Therefore, some of the inventive concepts are focused on replacing the traditional rigid cold plate base with a novel deformable or conformable base plate that will allow controlled displacements on pre-defined regions. From one perspective, the conformable base plate is conformable in that when sandwiched between the coolant fluid and the computer chip, the conformable base plate will conform to the shape of the computer chip. Further, if the shape of the computer chip changes, the shape of the conformable base shape will also change to continue conforming to the new shape of the computer chip. In some implementations, such as the implementations described relative to FIGS. 5 and 6, regions of the conformable base plate that are desired to remain stiffer can be reinforced with rigid heat transfer structures, such as triply periodic minimal surfaces (TPMS) that both enhance their rigidity and promote efficient heat exchange. The conformable base plate regions associated with larger displacements can employ less rigid heat transfer structures such as pin fins that can be more widely spaced from one another. Forces that can cause deformation of the conformable base plate to conform to the computer chip can be provided by the internal pressure of the coolant fluid flowing through the cold plate assembly against the conformable base plate, from forces from the computer chip, and/or from the construction of the conformable base plate, such as the bi-metallic construction of FIG. 4.

Traditional rigid cold plates are designed without allocating for any prescribed warpage to their base. The bases are also flattened to a planar configuration as part of the manufacturing process before assembly with the computer chip. These aspects induce failure modes such as TIM pump out. The presence of TIM pump out in the chip/cold plate assembly will eventually lead to a significant degradation in heat transfer and constant thermal events that will not only decrease the performance of the computer chip but it will also hinder its reliability. In contrast, the allowed deformation of the conformable base plate will increase the rate of heat exchange at the conformable base plate as the smaller gaps in between surfaces will allow for a lower thermal resistance in the stacked computer chip and conformable base plate of the cold plate assembly.

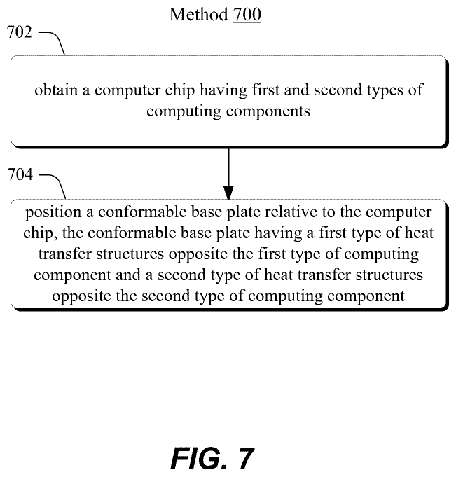

FIG. 7 shows a flowchart of an example method for implementing some of the present conformable base plate concepts.

Block 702 can obtain a computer chip having first and second types of computing components. For instance, the computer chip can include processors of different types and memory/storage, among others. These different types of computing components can produce different heat loads. In some cases, the processors are grouped together and the memory is grouped together. In other cases, individual processors and memory can be grouped together as ‘chiplets.’ The computer chip can have a first shape under a first set of conditions, such as ambient temperature and a second shape at a second temperatures, such as operational temperature. These changes in shape tend to become more pronounced as computer chip designs get bigger in diameter in round configurations or in length and/or width in rectangular configurations. Stated another way, the distance of deflection in the z direction tends to be larger when the dimensions in the x or y directions are larger.

Block 704 can position a conformable base plate relative to the computer chip. The conformable base plate has a first type of heat transfer structures opposite (e.g., overlying) the first type of computing component and a second type of heat transfer structure opposite the second type of computing component. The first type of heat transfer structure may be configured to increase a rate of heat transfer to coolant fluid that flows past. The second type of heat transfer structure may be configured to balance heat transfer and flexibility of the underlying region of the conformable base plate (e.g., the first type of heat transfer structure may make the underlying region of the conformable base plate stiffer than the second type of heat transfer structure).

The conformable base plate is ‘conformable’ in that it will conform to the shape of the computer chip even if the shape of the computer chip changes. This conformable nature contributes to a uniform gap along a contact zone between the computer chip and the conformable base plate. Further, the uniformity of the gap is maintained if the shape of the computer chip (and the conformable base plate) changes. This gap maintenance retains TIM between the computer chip and the conformable base plate along the contact zone through multiple shape changes. Retention of the TIM maintains the designed thermal transfer rate of the cold plate assembly and allows the computer chip to be operated at intended design parameters throughout its lifespan.

### ADDITIONAL EXAMPLES

Various examples are described above. Additional examples are described below. One example includes a system comprising a cold plate assembly comprising a conformable base plate secured to a manifold to define a fluid passageway and a computer chip biased against the conformable base plate opposite the fluid passageway, the computer chip having a first shape at ambient temperature and a second different shape at a higher operating temperature, the conformable base plate conforming to the first shape at the ambient temperature and the second shape at the higher operating temperature.

Another example can include any of the above and/or below examples where the conformable base plate conforms to the first shape of the computer chip to create a generally uniform gap along a contact zone between the conformable base plate and the computer chip at ambient temperature and conforms to the second shape of the computer chip to maintain the generally uniform gap along the contact zone at the higher operating temperature.

Another example can include any of the above and/or below examples where the conformable base plate comprises a first side facing the manifold and a second side facing the computer chip, and wherein the base plate comprises heat transfer structures extending from the first surface into the fluid passageway.

Another example can include any of the above and/or below examples where the heat transfer structures are non-uniform relative to one another when viewed along a cross-section that is orthogonal to the first surface and passes through a periphery and a center of the base plate.

Another example can include any of the above and/or below examples where the non-uniformity relates to height, spacing, and/or interconnectedness.

Another example can include any of the above and/or below examples where a first subset of the heat transfer structures are interconnected with one another and a second subset of the heat transfer structures are not interconnected with one another.

Another example can include any of the above and/or below examples where at ambient temperature the first shape of the computer chip is convex along the cross-section and a first shape of the conformable base plate is concave towards the computer chip, and wherein at operating temperature the second shape of the computer chip is more convex and a second shape of the conformable base plate is more concave than ambient temperature, or wherein at operating temperature the second shape of the computer chip is less convex and the second shape of the base plate is less concave than at ambient temperature.

Another example can include any of the above and/or below examples where the computer chip includes multiple processors and multiple other computer components and wherein the heat transfer structures over the multiple processors are different than the heat transfer structures over the multiple other computer components.

Another example includes a cold plate assembly comprising a manifold defining a perimeter extending around a center, a conformable base plate having generally opposing first and second sides, the conformable base plate defining a perimeter extending around a center, the first side of the perimeter of the conformable base plate secured to the perimeter of the manifold to define a fluid passageway between the center of the conformable base plate and the center of the manifold, the first side of the conformable base plate also defining first and second types of heat transfer structures that extend into the fluid passageway, and a computer chip positioned against the second side of the conformable base plate from the manifold and having a first type of computing component positioned under the first type of heat transfer structure and a second different type of computing component positioned under the second type of heat transfer structure.

Another example can include any of the above and/or below examples where the first type of heat transfer structures comprises interconnected heat transfer structures that stiffen an underlying zone of the conformable base plate, and wherein the second type of heat transfer structures are not interconnected and provide less stiffening of the base plate.

Another example can include any of the above and/or below examples where the computer chip changes shape and the conformable base plate deforms to follow a shape of the computer chip.

Another example can include any of the above and/or below examples where the computer chip has a first shape at ambient temperature and a second different shape at operating temperatures.

Another example can include any of the above and/or below examples where fluid pressure from the fluid passageway deforms the base plate to follow the first shape and the second shape.

Another example can include any of the above and/or below examples where the cold plate assembly further comprises a thermal interface material positioned along a contact zone extending along the conformable base plate and the computer chip.

Another example can include any of the above and/or below examples where the deformation of the conformable base plate maintains the contact zone at a generally uniform gap at both the ambient temperature and the operating temperature.

Another example can include any of the above and/or below examples where the generally uniform gap at the ambient temperature is within +/−20% of the generally uniform gap at the operating temperature.

Another example can include any of the above and/or below examples where a width of the computer chip is in a range of about 20 millimeters to about 400 millimeters and the shape of the computer chip changes in a range of about 50 microns to about 500 microns toward or away from the conformable base plate when the computer chip heats from ambient temperature to operating temperature.

Another example can include any of the above and/or below examples where a thickness of the conformable base plate is about 200 microns to about 500 microns and a thickness of the computer chip is about 500 microns to about 1000 microns.

Another example can include any of the above and/or below examples where a thickness of the conformable base plate is about 25% to about 100% of a thickness of the computer chip

Another example includes a cold plate assembly comprising a manifold and a conformable cold plate positioned against the manifold to form a fluid passageway and wherein the conformable cold plate is configured to conform to a shape of a computer chip positioned against the conformable cold plate when exposed to fluid pressure from the fluid passageway.

### CONCLUSION

Although techniques, methods, devices, systems, etc., pertaining to conformable base plate concepts are described in language specific to structural features and/or methodological acts, it is to be understood that the subject matter defined in the appended claims is not necessarily limited to the specific features or acts described. Rather, the specific features and acts are disclosed as example forms of implementing the claimed methods, devices, systems, etc.

1. A system, comprising:
a cold plate assembly comprising a conformable base plate secured to a manifold to define a fluid passageway; and,
a computer chip biased against the conformable base plate opposite the fluid passageway, the computer chip having a first shape at ambient temperature and a second different shape at a higher operating temperature, the conformable base plate conforming to the first shape at the ambient temperature and the second shape at the higher operating temperature.

2. The system of claim 1, wherein the conformable base plate conforms to the first shape of the computer chip to create a generally uniform gap along a contact zone between the conformable base plate and the computer chip at ambient temperature and conforms to the second shape of the computer chip to maintain the generally uniform gap along the contact zone at the higher operating temperature.

3. The system of claim 1, wherein the conformable base plate comprises a first side facing the manifold and a second side facing the computer chip, and wherein the base plate comprises heat transfer structures extending from the first surface into the fluid passageway.

4. The system of claim 3, wherein the heat transfer structures are non-uniform relative to one another when viewed along a cross-section that is orthogonal to the first surface and passes through a periphery and a center of the base plate.

5. The system of claim 4, wherein the non-uniformity relates to height, spacing, and/or interconnectedness.

6. The system of claim 5, wherein a first subset of the heat transfer structures are interconnected with one another and a second subset of the heat transfer structures are not interconnected with one another.

7. The system of claim 6, wherein at ambient temperature the first shape of the computer chip is convex along the cross-section and a first shape of the conformable base plate is concave towards the computer chip, and wherein at operating temperature the second shape of the computer chip is more convex and a second shape of the conformable base plate is more concave than ambient temperature, or wherein at operating temperature the second shape of the computer chip is less convex and the second shape of the base plate is less concave than at ambient temperature.

8. The system of claim 7, wherein the computer chip includes multiple processors and multiple other computer components and wherein the heat transfer structures over the multiple processors are different than the heat transfer structures over the multiple other computer components.

9. A cold plate assembly, comprising:
a manifold defining a perimeter extending around a center;
a conformable base plate having generally opposing first and second sides, the conformable base plate defining a perimeter extending around a center, the first side of the perimeter of the conformable base plate secured to the perimeter of the manifold to define a fluid passageway between the center of the conformable base plate and the center of the manifold, the first side of the conformable base plate also defining first and second types of heat transfer structures that extend into the fluid passageway; and,
a computer chip positioned against the second side of the conformable base plate from the manifold and having a first type of computing component positioned under the first type of heat transfer structure and a second different type of computing component positioned under the second type of heat transfer structure.

10. The cold plate assembly of claim 9, wherein the first type of heat transfer structures comprises interconnected heat transfer structures that stiffen an underlying zone of the conformable base plate, and wherein the second type of heat transfer structures are not interconnected and provide less stiffening of the conformable base plate.

11. The cold plate assembly of claim 10, wherein the computer chip changes shape and the conformable base plate deforms to follow a shape of the computer chip.

12. The cold plate assembly of claim 11, wherein the computer chip has a first shape at ambient temperature and a second different shape at operating temperatures.

13. The cold plate assembly of claim 12, wherein fluid pressure from the fluid passageway deforms the base plate to follow the first shape and the second shape.

14. The cold plate assembly of claim 13, further comprising a thermal interface material positioned along a contact zone extending along the conformable base plate and the computer chip.

15. The cold plate assembly of claim 14, wherein the deformation of the conformable base plate maintains the contact zone at a generally uniform gap at both the ambient temperature and the operating temperature.

16. The cold plate assembly of claim 15, wherein the generally uniform gap at the ambient temperature is within +/−20% of the generally uniform gap at the operating temperature.

17. The cold plate assembly of claim 16, wherein a width of the computer chip is in a range of about 20 millimeters to about 400 millimeters and the shape of the computer chip changes in a range of about 50 microns to about 500 microns toward or away from the conformable base plate when the computer chip heats from ambient temperature to operating temperature.

18. The cold plate assembly of claim 17, wherein a thickness of the conformable base plate is about 200 microns to about 500 microns and a thickness of the computer chip is about 500 microns to about 1000 microns.

19. The cold plate assembly of claim 17, wherein a thickness of the conformable base plate is about 25% to about 100% of a thickness of the computer chip.

20. A cold plate assembly, comprising:
a manifold; and,
a conformable cold plate positioned against the manifold to form a fluid passageway and wherein the conformable cold plate is configured to conform to a shape of a computer chip positioned against the conformable cold plate when exposed to fluid pressure from the fluid passageway.
